(19) United States
(12) Patent Application Publication
(10) Pub. No.: US 2006/0073621 A1
(43) Pub. Date: Apr. 6, 2006

(54) Group III-nitride based HEMT device with insulating GaN/AlGaN buffer layer

(75) Inventors: Michael A. Kneissel, Mountain View, CA (US); Peter Kiesel, Palo Alto, CA (US); William Wong, San Carlos, CA (US); David W. Treat, San Antonio, TX (US)

Correspondence Address: OLIFF & BERRIDGE, PLC., P.O. BOX 19928, ALEXANDRIA, VA, 22320, US

(73) Assignee: PALO ALTO RESEARCH CENTER INCORPORATED, Palo Alto, CA (US)

(21) Appl. No.: 10/954,202

(22) Filed: Oct. 1, 2004

(51) Int. Cl. H01L 21/00

(52) U.S. Cl. 438/21

(57) ABSTRACT

Various exemplary embodiments of the devices and methods for this invention provide for a semiconductor structure and a method of manufacturing a semiconductor structure that includes providing an aluminum nitride nucleation layer over a substrate, providing an undoped AlGaN buffer layer over the aluminum nitride nucleation layer, providing an undoped GaN over the AlGaN buffer layer, providing a plurality of AlGaN layers over the GaN layer wherein the plurality of aluminum GaN layers comprise a first layer provided over the undoped GaN layer, a second layer provided over the first layer and the third layer provided over the second layer, providing a source electrode and a drain electrode, through the first, second and third aluminum gallium nitride layers, the source electrode and the drain electrode being in electrical contact with the gallium nitride layer and providing a gate electrode over the third aluminum gallium nitride layer.

### BACKGROUND OF THE INVENTION

1. Field of Invention

This invention relates to transistor devices and in particular relates to nucleation layers in the transistor devices.

2. Description of Related Art

Gallium nitride based high electron mobility transistors (HEMTs) are very attractive electronic devices because of their high breakdown fields, high temperature stability and high power, high frequency handling capability. HEMTs may be used for a variety of applications such as, cell phone base stations or automobile electronics. Currently, most gallium nitride HEMTs are grown by molecular beam epitaxy (MBE) because HEMT devices require an insulating buffer layer for high speed operation. Unfortunately, MBE is a very slow growth technique.

The background impurity concentrations for MBE-grown gallium nitride can be substantially low, accordingly, gallium nitride films grown via MBE are generally expected to be sufficiently insulating for most high speed device applications, but the nucleation layer underneath the gallium nitride layer is generally conducting and has a negative impact on the performance of the device. Moreover, because MBE is a slow growth technique, it is not suitable for mass production. On the other hand, metal-organic chemical vapor deposition (MOCVD) allows for mass production, but gallium nitride films grown on silicon carbon or sapphire using MOCVD generally exhibit relatively high n-type conductivity because of the relatively high concentrations of background impurity such as, for example, silicon or oxygen, in gallium nitride films grown by MOCVD. A conductive gallium nitride buffer layer results in parasitic capacitances, which are detrimental to high speed operation of gallium nitride based HEMT devices.

### SUMMARY OF THE INVENTION

In light of the above described problems and shortcomings, various exemplary embodiments of the systems and methods according to this invention provide for a method of manufacturing a semiconductor structure, the method including at least providing an aluminum nitride nucleation layer over a substrate, providing an undoped aluminum gallium nitride buffer layer over the aluminum nitride nucleation layer, and providing an undoped gallium nitride layer over the aluminum gallium nitride buffer layer.

Moreover, various exemplary embodiments of the methods of this invention provide for a method of manufacturing an HEMT device, the method including providing a plurality of aluminum gallium nitride layers over a semiconductor structure that includes an aluminum nitride nucleation layer over a substrate, an undoped aluminum gallium nitride buffer layer over the aluminum nitride nucleation layer and a gallium nitride layer over the aluminum gallium nitride buffer layer, wherein the plurality of aluminum gallium nitride layers include a first layer provided over the gallium nitride layer, a second layer provided over the first layer and a third layer provided over the second layer.

Also, various exemplary embodiments of the systems and methods of this invention provide for a method of manufacturing a field effect transistor, the method including providing a source electrode and a drain electrode through the first, second and third aluminum gallium nitride layers, as described above, of a high electron mobility transistor structure, the source electrode of the drain electrode being in electrical contact with the undoped gallium nitride layer of the HEMT and providing a gate electrode over the third aluminum gallium nitride layer.

Moreover, various exemplary embodiments of the devices of this invention provide for a semiconductor structure that includes an aluminum nitride nucleation layer over a substrate, an undoped aluminum gallium nitride buffer layer over the aluminum nitride nucleation layer and an undoped gallium nitride layer over the aluminum gallium nitride buffer layer.

Furthermore, various exemplary embodiments of the devices of this invention provide for a high electron mobility transistor structure that includes an aluminum nitride nucleation layer over a substrate, an aluminum gallium nitride buffer layer over the aluminum nitride nucleation layer, an undoped gallium nitride layer over the aluminum gallium nitride buffer layer and a plurality of aluminum gallium nitride layers over the gallium nitride layer, wherein the plurality of aluminum gallium nitride layers comprise a first layer provided over the gallium nitride layer, a second layer provided over the first layer and a third layer provided over the second layer.

Finally, various exemplary embodiments of the devices according to this invention provide for a field effect transistor structure that includes an HEMT as described above, a source electrode and a drain electrode through the first, second and third aluminum gallium nitride layers of the HEMT, the source electrode and the drain electrode being in electrical contact with the undoped gallium nitride layer and a gate electrode formed over the third aluminum gallium nitride layer.

Finally, various exemplary embodiments of the methods of this invention provide for separating the sapphire substrate from the remaining semiconductor structure, transferring the remaining semiconductor structure to a second substrate and attaching the remaining semiconductor structure to the second substrate using, for example, one or more insulating bonding layers.

### BRIEF DESCRIPTION OF THE DRAWINGS

Various exemplary embodiments of the systems and methods of this invention will be described in detail, with reference to the following figures, wherein:

FIG. 1 is a flowchart illustrating a method of manufacturing a layered aluminum nitride and aluminum gallium nitride structure according to various exemplary embodiments of this invention;

FIG. 2 is a flowchart illustrating a method of manufacturing a semiconductor according to various exemplary embodiments of this invention;

FIG. 3 is a flowchart illustrating a method of manufacturing a high electron mobility transistor according to various exemplary embodiments of this invention;

FIG. 4 is an illustration of an insulating aluminum gallium nitride layer on a sapphire substrate grown with an aluminum nitride nucleation layer according to various exemplary embodiments of this invention;

FIG. 5 is an illustration of an insulating gallium nitride/aluminum gallium nitride/aluminum nitride template on sapphire grown by MOCVD according to exemplary embodiments of this invention;

FIGS. 6a-6b are illustrations of a gallium nitride based HEMT layer structure grown by MOCVD on insulating gallium nitride/aluminum gallium nitride/aluminum nitride template on sapphire and a field electron transistor (FET) device structure with titanium/aluminum source and drain and palladium gate contacts according to various exemplary embodiments of the invention;

FIG. 7 shows variable temperature Hall measurements for an HEMT structure grown by MOCVD on an insulating GaN/AlGaN/AlN template on sapphire substrate, according to various exemplary embodiments of this invention;

FIG. 8 shows the transfer (left) and output characteristics (right) of a GaN HFET device before lift off, according to various exemplary embodiments of this invention; and

FIG. 9 shows the transfer (left) and output characteristics (right) of a GaN HFET device after substrate removal and transfer by excimer laser lift-off, according to various exemplary embodiments of this invention.

### DETAILED DESCRIPTION OF PREFERRED EMBODIMENTS

These and other features and advantages of this invention are described in, or are apparent from, the following detailed description of various exemplary embodiments of the systems and methods according to this invention.

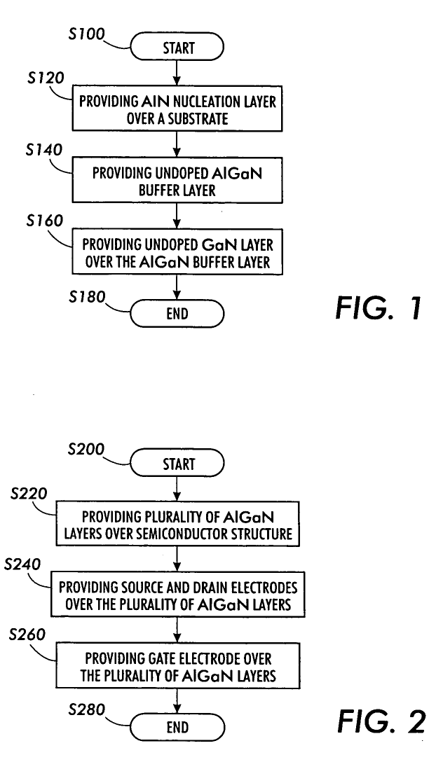

FIG. 1 is a flowchart illustrating a method of manufacturing a layered aluminum nitride (AlN) and aluminum gallium nitride (AlGaN) structure according to various exemplary embodiments of this invention. The method starts in step S100 and continues to step S120, during which an AlN nucleation layer is provided over a substrate. According to various exemplary embodiments of this invention, the substrate can be sapphire, aluminum nitride (AlN), gallium nitride (GaN), silicon carbide (SiC), or silicon (Si). According to various exemplary embodiments, when an AlN or GaN substrate is used, it might not be necessary to provide an AlN nucleation layer. Instead, MOCVD growth can be initiated by immediately providing the AlGaN buffer layer without the AlN buffer layer.

Next, control continues to step S140. During step S140, an undoped AlGaN buffer layer is provided over the AlN nucleation layer. According to various exemplary embodiments, the AlGaN buffer layer is 3 microns thick and is provided via metal-organic chemical vapor deposition (MOCVD). According to various exemplary embodiments, the AlN nucleation layer is also provided via MOCVD.

After the buffer layer is provided during step S140, control continues to step S160. During step S160, an undoped gallium nitride (GaN) layer is provided over the undoped AlGaN buffer layer. According to various exemplary embodiments, the undoped GaN layer is 400 nm thick. According to various exemplary embodiments, the GaN layer is provided via MOCVD. Next, control continues to step S180, where the method ends.

FIG. 2 is a flowchart illustrating a method of manufacturing a semiconductor according to various exemplary embodiments of this invention. The method starts in step S200 and continues to step S220, during which a plurality of AlGaN layers are provided over a semiconductor structure. In various exemplary embodiments, the semiconductor structure may include a substrate, an AlN nucleation layer provided over the substrate, an AlGaN buffer layer provided over the AlN nucleation layer, and an undoped GaN layer provided over the undoped AlGaN buffer layer. According to various exemplary embodiments, the plurality of AlGaN layers are 5 nm, 15 nm and 3 nm thick, respectively. According to various exemplary embodiments, there are three aluminum gallium layers, the first layer is undoped, the second layer is silicon doped, and the third layer is undoped, wherein the first layer is the layer that is provided over the GaN layer. Next, control continues to step S240.

During step S240, a source and a drain electrode are provided through the plurality of AlGaN layers. According to various exemplary embodiments of this invention, the source and drain electrodes are made of a material consisting mainly of titanium/aluminum (Ti/Al). According to various exemplary embodiments, other possible electrode materials or combinations of electrode materials include Ti/Al/Mo/Au, Ti/Al/Ni/Au, Ti/Al/Pt/Au, Ti/Al/Au, Ti/Au, and V/AI/Pt/Au. A typical example of layer thicknesses for a Ti/Al/Ni/Au contact would be, for example, 20 nm Ti, 50 nm Al, 50 nm Ni and 50 nm Au. According to various exemplary embodiments, such an exemplary contact may be annealed in order to achieve a lower contact resistance. Typical exemplary annealing conditions are, for example, a temperature of 500° C. to 900° C., a gaseous atmosphere such as a nitrogen-filled environment, and for a time period of 30 seconds to 30 minutes. Optimal annealing conditions will depend on the contact material or combination of materials. According to various exemplary embodiments, the source and the drain electrodes are in electrical contact with the GaN layer over which the plurality of AlGaN layers are provided. Next, control continues to step S260. During step S260, a gate electrode is provided over the plurality of AlGaN layers. According to various exemplary embodiments of this invention, the gate electrode is a Schottky contact made out of a high work function metal such as, for example, platinum. Possible gate electrode materials or material combinations include Pt/Au, Pd/Au, Pt/Ti/Au, Pd/Ti/Au, Ni/Au, Ir/Au, Re/Au or combination thereof. Next, control continues to step S280, where the method ends.

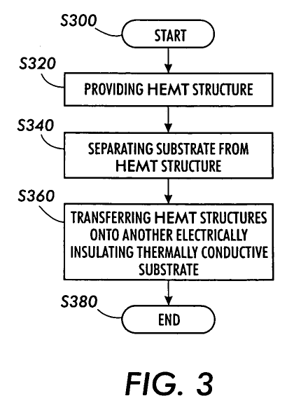

FIG. 3 is a flowchart illustrating a method of manufacturing a high electron mobility transistor (HEMT), according to various exemplary embodiments of this invention. The method starts in step S300 and continues to step S320. During step S320, an HEMT structure is provided that includes a substrate over which an AlN nucleation layer is provided, an AlGaN buffer layer is provided over the nucleation layer, a GaN layer is provided over the buffer layer, a plurality of AlGaN layers are provided over the GaN layer, and a source, drain and gate electrode are provided through the plurality of AlGaN layers, in a structure similar to the structure described above. Next, control continues to step S340.

During step S340, the substrate is separated from the rest of the HEMT structure. According to various exemplary embodiments, a handle substrate is first bonded, for example, by using an epoxy, on the surface of the HEMT structure. According to various exemplary embodiments, separating the first substrate (or sapphire) from the rest of the HEMT structure is performed by, for example, decomposing the buffer layer by laser irradiation through the transparent first substrate. For the laser irradiation, a high power excimer laser can be used, with an emission wavelength that is shorter than the wavelength corresponding to the bandgap of the AlGaN buffer layer. The emission wavelength of the excimer lasers depends on the gas used. For example, a XeCl excimer laser typically emits at 308 nm, a KrF laser at 248 nm, an ArF laser at 193 nm and a F₂ laser at 157 nm. According to various exemplary embodiments, the intensity of the excimer laser pulse is typically 100-800 mJ/cm². Next, control continues to step S360. During step S360, the HEMT structure is then transferred onto the handle substrate, which results in an inverted structure. The HEMT structure on the handle wafer is then bonded onto another substrate. According to various exemplary embodiments, the other substrate is a more electrically insulating and more thermally conductive substrate than the first substrate. According to various exemplary embodiments, the first bonded interface between the HEMT structure and the handle wafer is selectively etched away to release the handle wafer. The HEMT structure is then transferred onto the final substrate in the original non-inverted orientation. Next, control continues to step S380, where the method ends. Details regarding the excimer laser lift-off technique can be found in U.S. Pat. No. 6,562,648 for double transfer method for InGaN-based laser diodes, U.S. Pat. No. 6,757,314, U.S. Pat. No. 6,627,921, U.S. Pat. No. 6,448,102, and U.S. Pat. No. 6,365,429, which are incorporated herein in their entirety.

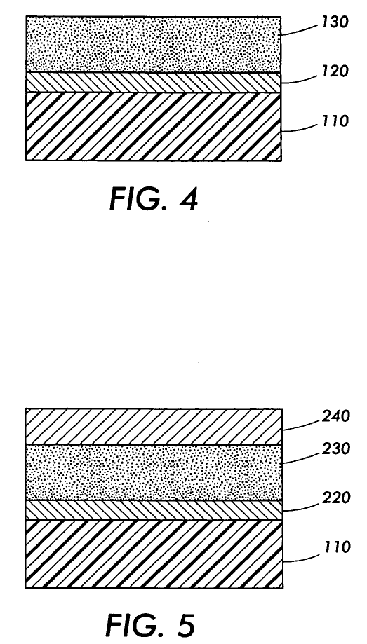

FIG. 4 is an illustration of an insulating AlGaN layer 130 on a sapphire substrate 110 grown with an AlN nucleation layer 120 forming a layered structure 100, according to various exemplary embodiments of this invention. The nucleation layer 120 is, according to various exemplary embodiments, made of AlN. According to various exemplary embodiments, the layered structure illustrated in FIG. 4 is formed by forming the nucleation layer 120 over the substrate 110 by MOCVD, and then forming the buffer layer 130 over the nucleation layer 120 also via MOCVD. According to various exemplary embodiments of this invention, the thickness of the nucleation layer 120 is 20 nm and the thickness of the AlGaN buffer layer 130 is typically 1-4 microns. According to various exemplary embodiments, the Al mole fraction in the AlGaN buffer layer 130 is typically between 5% and 20% but can also be higher.

FIG. 5 is an illustration of an insulating GaN/AlGaN/AlN template on sapphire 200 grown by MOCVD which is, according to various exemplary embodiments of this invention, designed to produce an insulating AlGaN buffer layer 230 on the sapphire substrate 210 and GaN layer on top. MOCVD is a standard growth technique for III/V laser material and is well-known in the art. According to various exemplary embodiments, MOCVD growth is typically performed on a 2-inch or a 3-inch diameter sapphire substrate wafer. According to various exemplary embodiments, the substrate can be a C-face (0001) or A-face (1120) oriented sapphire (Al₂O₃) substrate. According to various exemplary embodiments, the sapphire substrate wafers are of standard specifications including an epitaxial polish on one side, with a typical thickness of 10 to 17 mil. Other examples of substrates include, but are not limited to, 4H—SiC, 6H—SiC, AlN, Spinel (MgAl₂O₄), and GaN. In the case of growth on a GaN or AlN substrate, the second III-V nitride layer can be directly formed on top of the substrate without the deposition of a nucleation layer. According to various exemplary embodiments, the growth temperatures are typically 400 to 600° C. for the AlN nucleation layer (typically 550° C.) and 900 to 1200° C. for the AlGaN and GaN layers (typically 1100° C.). In addition, the reactor pressure may be controlled to fall between 50 Torr and 740 Torr. According to various exemplary embodiments, as organometallic precursors for the MOCVD growth, TMGa (trimethylgallium), TMAl (trimethylaluminum), TMIn (trimethylindium) and TEGa (triethylgallium) can also be used for the group III elements and NH₃ (ammonia) can be used as the nitrogen source, and Hydrogen and/or nitrogen can be used as a carrier gas for the metal-organic sources. For the n-doping, 100 ppm SiH₄ diluted in H₂ can be used. Other examples of n-type dopants include, but are not limited to, O, Se, and Te. According to various exemplary embodiments, an AlN nucleation layer 220, instead of a GaN nucleation layer, is used as a nucleation layer or a wetting layer on the sapphire substrate 210. Gallium nitride nucleation layers have shown to be relatively conductive, and are generally a source of residual conductivity found in undoped AlGaN films. According to various exemplary embodiments, the MOCVD growth process of the layered structure 200 of this invention is similar to the growth process for a conventional structure. After the deposition of the thin (20 nm), initially amorphous, AlN nucleation layer 220 at a temperature of about 550° C., the growth temperature is raised to about 1100° C. and a 3 μm thick nominally undoped AlGaN buffer layer 230 is deposited, nominally undoped meaning that no dopants were intentionally incorporated into the film by, for example, flowing a doping gas such as SiH₄ during deposition. However, due to limits in the purity of metal-organic and gas sources and due to contamination from the reactor vessel, some impurities may still be incorporated unintentionally during the growth process. It is generally accepted that O, Si and C, are incorporated in GaN and AlGaN films during the growth process in small quantities. The background impurity concentration for MOCVD grown films is typically 10¹⁵-10¹⁷ cm⁻³. However, the conductivity of the AlGaN/AlN layer, according to various exemplary embodiments, is found to remain extremely low, by incorporating a modest amount of aluminum (5%-20%) into the high-temperature grown AlGaN buffer layer 230. For example, a conventional 3 μm thick nominally undoped GaN buffer layer grown by MOCVD on sapphire exhibits a typical resistance in the range of about 100 Ω-cm. On the other hand, the measured resistance of the AlGaN 230/AlN 220 films on the sapphire substrate 210 is, for instance, more than 10 GΩ-cm.

However, an AlGaN film on sapphire alone would not provide the best starting template for an HEMT device, because the electron mobilities in AlGaN are significantly lower than in GaN (e.g., room temperature electron mobility in bulk GaN is typically 250 cm²/Vs, compared to an electron mobility in bulk AlGaN of typically <100 cm²/Vs). Therefore, the ideal starting template for a GaN HEMT structure should terminate with a GaN layer 240. However, because of the expected polarization charges at the AlGaN/GaN interface and/or the GaN surface, a thick GaN film 240 grown on the AlGaN buffer layer 230 might be conductive and therefore defeat the purpose of an insulating template for the HEMT structure.

According to various exemplary embodiments, experimental measurements obtained from 500 nm thick nominally undoped GaN layer 240 grown on top of a high resistivity AlGaN buffer layer 230 generally do not show a drastic effect. Measurements on the nominally undoped GaN/AlGaN/AlN heterostructure films generally show resistance values similar to the AlGaN/AlN films on sapphire, at about 1 GΩ-cm. This resistance is seven orders of magnitude higher than for MOCVD-grown undoped GaN layers 240 on a sapphire substrate 210, and more than sufficient for high-speed HEMT applications.

According to various exemplary embodiments, the measured room-temperature resistance values for the different MOCVD grown layer structures are listed in Table 1 below.

TABLE 1

| LAYER STRUCTURE | | RESISTANCE |
|---|---|---|
| 3 | μm GaN: un on sapphire with GaN nucleation | 100 Ω-cm |
| | layer | |
| 3 | μm GaN: un on sapphire with AlN nucleation | 15 MΩ-cm |
| | layer | |
| 3 | μm Al_{0.01}Ga_{0.93}N: un on sapphire with AlN | 10 GΩ-cm |
| | nucleation layer | |
| 3 | μm Al_{0.13}Ga_{0.87}N: un on sapphire with AlN | 10 GΩ-cm |
| | nucleation layer | |
| 0.5 | μm GaN: un on Al_{0.13}Ga_{0.87}N: un on | 10 MΩ-cm |
| | sapphire with AlN nucleation layer | |

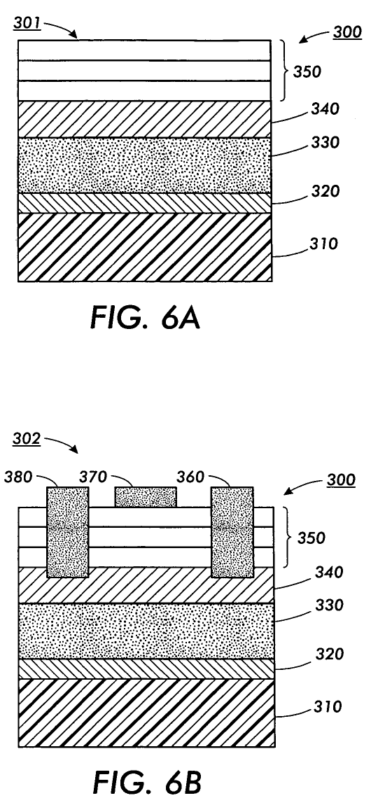

FIGS. 6a-6b are illustrations of a GaN-based HEMT layer structure 301 grown by MOCVD on insulating GaN 340/AlGaN 330/AlN 320 template on a sapphire susbtrate 310 and a field electron transistor (FET) device structure 302 with a titanium (Ti)/aluminum (Al) source electrode 380, a Ti/Al drain electrode 360, and a palladium gate contact 370, according to various exemplary embodiments of the invention.

According to various exemplary embodiments, a full HEMT structure 301 grown by MOCVD on a GaN 340/AlGaN buffer layer 330 structure on a sapphire substrate 310 is realized. The HEMT layer structure 301 and the complete FET device structure 302 are shown in FIGS. 6a-6b. According to various exemplary embodiments, the AlGaN HEMT layer 330 is deposited via MOCVD at 1100° C. in the same growth run as the rest of the GaN 340/AlGaN buffer layer 330 structure. According to various exemplary embodiments, a 5 nm thick, nominally undoped, AlGaN layer with a typical Al mole fraction of 25% is deposited, followed by a 15 nm thick Si-doped (Si concentration of about 5×10¹⁸ cm³) AlGaN layer with a typical Al mole fraction of 25%, and further followed by a 3 nm thick nominally undoped AlGaN layer with a typical Al mole fraction of 25%. The thicknesses, Al mole fractions and Si-doping concentrations may very for different HEMT devices, depending on the desired operation parameters. It is also possible to employ other exemplary variations of the proposed HEMT heterostructure that are well know to one skilled in the art. Room temperature Hall measurements show a sheet carrier concentration of 1.35×10¹³ cm⁻² and an electron mobility of 400 cm² Vs. Temperature-dependent Hall measurements show an almost constant electron concentration over the whole temperature range (80 K-450 K). The mobility increases to lower temperatures and shows saturation for temperatures below 100 K. This indicates that there is no significant impurity scattering. The carriers are separated from the impurities in the doped AlGaN layer 330 by forming a 2 dimensional electron gas at the GaN 340/AlGaN 330 interface.

In order to enable high-power operation for HEMT devices sufficient heat dissipation is essential to achieve this goal. Sapphire substrates, however, are not very good thermal conductors and therefore improved ways of heat sinking have to be developed. One approach is the use of flip-chip bonding. However, that approach is technically difficult, because the source, drain and gate contacts need to be electrically isolated, which requires a high degree of alignment accuracy for the flip-chip bonding process. Furthermore, the design of the bond-pads needs to be compatible with high frequency operation, which is also difficult to achieve.

According to various exemplary embodiments, another technique that may be used to improve heat sinking is integration by thin-film layer transfer. One exemplary approach to separating nitride-based thin films from the sapphire growth substrate is by excimer laser lift-off. Excimer laser lift-off technology allows the separation of the GaN HEMT structure 301 from the sapphire substrate 310 and the transfer of the films to an electrically insulating, but thermally conductive heat sink such as, for example, aluminum nitride (AlN), diamond, or boron nitride (BN). One issue in that process is to find an electrically insulating bonding layer to attach the GaN HEMT structure 301 to the heat sink, without generating a conductive interlayer. The heat transfer for a bonded HEMT structure 301 onto a thermally conductive substrate using a typical polymeric-based adhesive is largely dependent on the thermal conductivity of the adhesive layer. Modeling of such a structure having a nominal 1 micron thick bonding layer shows relatively high thermal resistance (˜107 W/K).

According to various exemplary embodiments, one technique that may be used to obtain better contact between the GaN HEMT structure 301 and the substrate 310 is to use surface roughening. Peak-to-peak contact can be obtained between the structure 301 backside and the substrate 310 surface, improving the contact area. According to various exemplary embodiments, other bonding processes such as direct bonding of thin film oxide surfaces may be employed to obtain a good thermal contact. According to various exemplary embodiments, the thermal resistance of a one micron thick silicon dioxide film is only 16 W/K based on the same modeling conditions used above.

Additional flexibility can also be gained by accessing the backside of the GaN-based device 301. For example, the AlGaN buffer 330/GaN 340 interface may introduce a conductive layer that would degrade the performance of the HEMT structure 301 at high frequency. By accessing the backside of the device through lift-off, this interface may be eliminated by etching the buffer layer 330 away. The processed film may then be transferred onto the new host substrate and finished. According to various exemplary embodiments, the insulating buffer layer structure could also be used in connection with GaN-based photodector devices or other electronic devices like GaN-based Heterostructure Bipolar Transistors (HBTs) or laser diodes and LEDs.

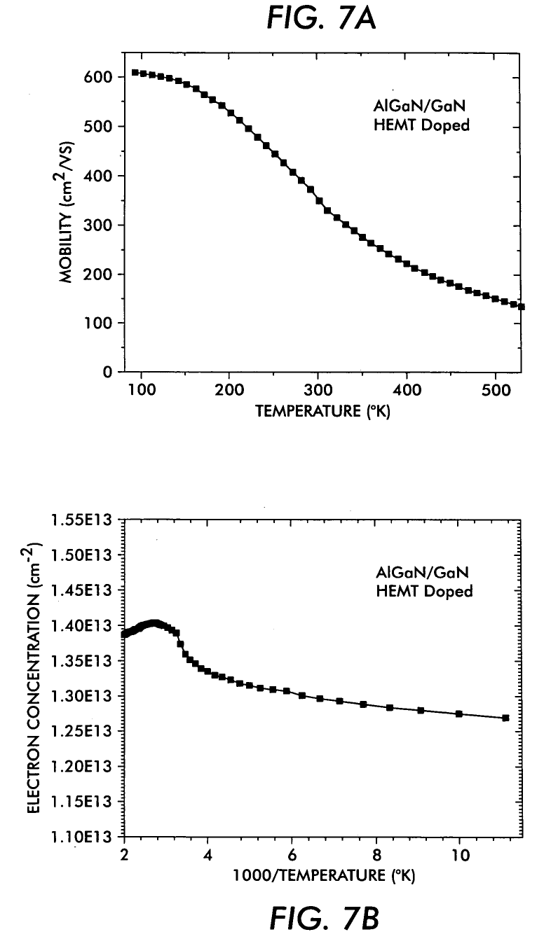

FIG. 7 shows variable temperature Hall measurements for an HEMT structure grown by MOCVD on an insulating GaN/AlGaN/AlN template on sapphire substrate, according to various exemplary embodiments of this invention. FIG. 7(a) shows the measured temperature dependence of the electron mobility, and 7(b) the measured carrier concentration vs. the inverse temperature. The temperature Hall measurements indicate that excellent ohmic contact and high channel currents of the source and drain contacts have been obtained.

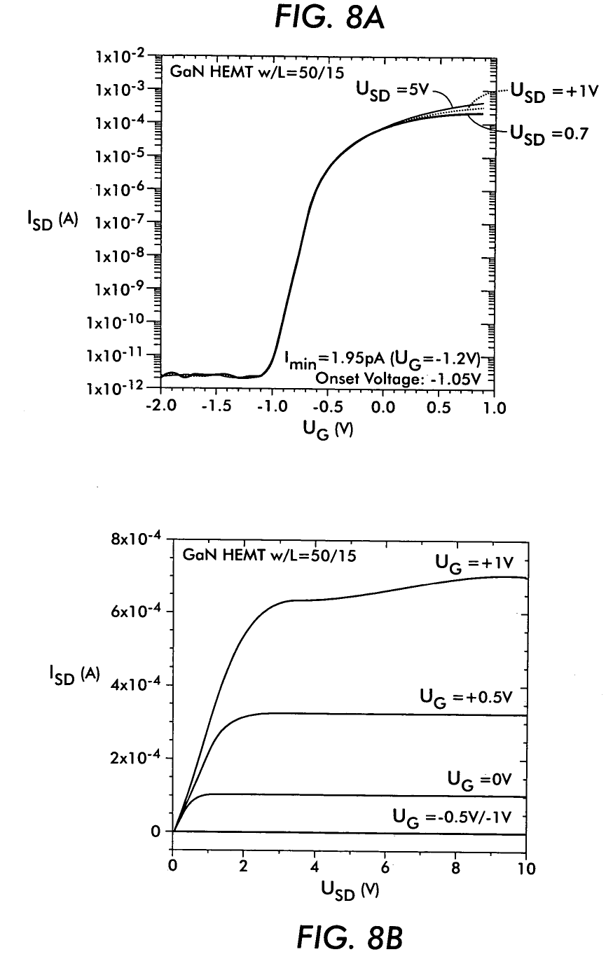

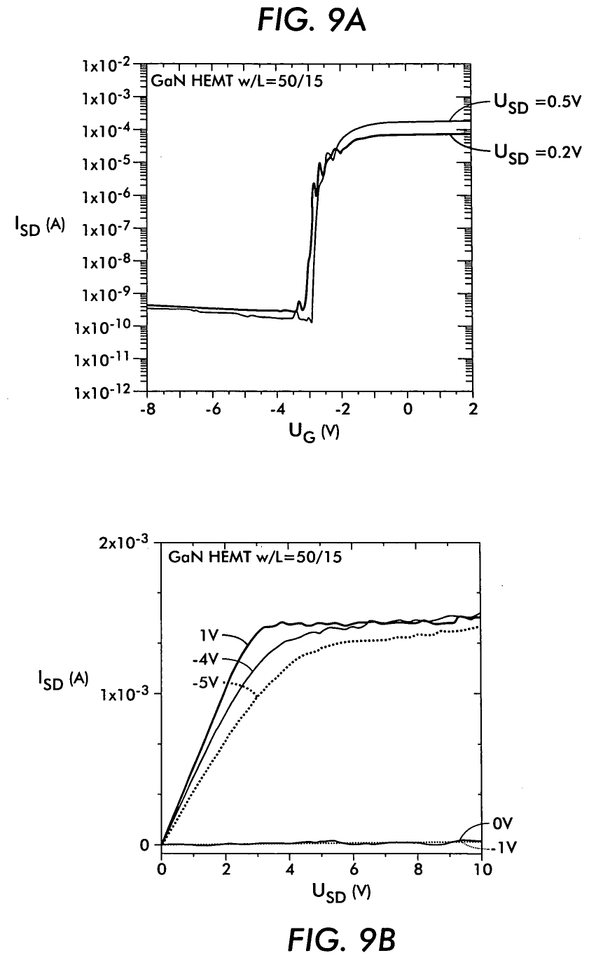

FIG. 8 shows the transfer (left) and output characteristics (right) of a GaN HFET device before lift off, according to various exemplary embodiments of this invention, and FIG. 9 shows the transfer (left) and output characteristics (right) of a GaN HFET device after substrate removal and transfer by excimer laser lift-off, according to various exemplary embodiments of this invention.

While the invention has been described in conjunction with exemplary embodiments, these embodiments should be viewed as illustrative, and not limiting. Various modifications, substitutes, or the like are possible within the spirit and scope of the invention.

What is claimed is:

1. A method of manufacturing a semiconductor structure, comprising:
providing a nucleation layer over a substrate;
providing an insulating buffer layer over the nucleation layer; and
providing a semiconducting layer over the insulating buffer layer.

2. The method of claim 1, wherein the nucleation layer is one of at least AlN and AlGaN.

3. The method of claim 1, wherein the buffer layer is AlGaN.

4. The method of claim 1, wherein the semiconducting layer is GaN.

5. The method of claim 1, wherein the nucleation layer has a thickness of about 20 nm.

6. The method of claim 1, wherein the insulating AlGaN buffer layer has a thickness of about 3 microns.

7. The method of claim 1, wherein the semiconducting layer has a thickness of about 500 nm.

8. The method of claim 1, wherein the undoped AlN layer is provided via metal-organic chemical vapor deposition.

9. The method of claim 1, wherein the undoped AlGaN buffer layer is provided via metal-organic chemical vapor deposition.

10. The method of claim 1, wherein the undoped GaN layer is provided via metal-organic chemical vapor deposition.

11. The method of claim 1, wherein the quantity of Aluminum in the AlGaN buffer layer is about 5 to 20%.

12. The method of claim 1, wherein the thickness of the insulating AlGaN buffer layer is about 1 to 5 microns.

13. The method of claim 1, wherein providing the AlN nucleation is performed at a temperature of about 550° C.

14. The method of claim 1, wherein providing the AlGaN buffer layer is performed at a temperature of about 1100° C.

15. The method of claim 1, wherein the substrate is one of at least a sapphire substrate, a silicon carbide substrate, a silicon substrate, an AlN substrate, a GaN substrate and a spinel substrate.

16. A method of manufacturing a high electron mobility transistor, comprising:
providing a plurality of AlGaN layers over the semiconductor structure produced by the method of claim 1, wherein the plurality of AlGaN layers comprise a first layer provided over the undoped GaN layer, a second layer provided over the first layer and a third layer provided over the second layer.

17. The method of claim 16, wherein the thickness of the first layer is about 5 nm, the thickness of the second layer is about 15 nm and the thickness of the third layer is about 3 nm.

18. The method of claim 16, wherein the plurality of AlGaN layers are provided at a temperature of about 1100° C.

19. The method of claim 16, wherein the first layer is undoped Al_{0.25}GaN_{0.75}N, the second layer is Si-doped Al_{0.25}Ga_{0.75}N and the third layer is undoped Al_{0.25}Ga_{0.75}N.

20. A method of manufacturing a field effect transistor, comprising:
providing a first electrode and a second electrode through the first, second and third semiconducting layers of the high electron mobility transistor structure produced by the method of claim 13, the first electrode and the second electrode being in electrical contact with the undoped semiconducting layer; and
providing a third electrode over the third semiconducting layer.

21. The method of claim 20, wherein the source electrode and the drain electrode are made of an alloy containing Ti and Al.

22. The method of claim 20, wherein the gate electrode comprises Palladium.

23. A method of manufacturing an electronic device, comprising:
providing a thin film heterostructure device that comprises a nucleation layer and a buffer layer onto a growth substrate;
bonding the heterostructure device onto a handle wafer via a bonding layer;
separating the growth substrate from the remaining heterostructure;
bonding the remaining heterostructure and the handle wafer to a second substrate; and
selectively etching away the bonding layer.

24. The method of claim 23, wherein at least one of the buffer layer comprises insulating AlGaN, the nucleation layer comprises AlN, and the heterostructure comprises AlGaN/GaN multilayers.

25. The method of claim 23, wherein the second substrate is electrically insulating and thermally conductive.

26. The method of claim 25, wherein the electrically insulating and thermally conductive substrate comprises at least one of diamond nitride, boron nitride, AlN and SiC.

27. A semiconductor structure, comprising:
an AlN nucleation layer over a substrate;
an insulating AlGaN buffer layer over the AlN nucleation layer; and
a semiconducting layer over the AlGaN buffer layer.

28. The semiconductor structure of claim 27, wherein the AlN nucleation layer has a thickness of about 20 nm.

29. The semiconductor structure of claim 27, wherein the insulating AlGaN buffer layer has a thickness of about 3 microns.

30. The semiconductor structure of claim 27, wherein the semiconducting layer is aGaN layer with a thickness of about 500 nm.

31. The semiconductor structure of claim 27, wherein the AlN nucleation layer is formed via metal organic chemical vapor deposition.

32. The semiconductor structure of claim 27, wherein the undoped AlGaN buffer layer is formed via metal organic chemical vapor deposition.

33. The semiconductor structure of claim 27, wherein the GaN layer is formed via metal organic chemical vapor deposition.

34. The semiconductor structure of claim 27, wherein the quantity of Aluminum in the AlN nucleation layer is about 5 to 20%.

35. The semiconductor structure of claim 27, wherein the thickness of the undoped AlGaN buffer layer is about 1 to 5 microns.

36. The semiconductor structure of claim 27, wherein the AlN nucleation is formed at a temperature of about 550° C.

37. The semiconductor structure of claim 27, wherein the AlGaN buffer layer is formed at a temperature of about 1100° C.

38. The semiconductor structure of claim 27, wherein the substrate is a sapphire substrate.

39. A high electron mobility transistor structure, comprising:
a plurality of AlGaN layers over the semiconductor structure of claim 27, wherein the plurality of AlGaN layers comprise a first layer provided over the undoped GaN layer, a second layer provided over the first layer and a third layer provided over the second layer.

40. The high electron mobility transistor structure of claim 39, wherein the thickness of the first layer is about 5 nm, the thickness of the second layer is about 15 nm and the thickness of the third layer is about 3 nm.

41. The high electron mobility transistor structure of claim 39, wherein the AlGaN layer is formed at a temperature of about 1100° C.

42. The high electron mobility transistor structure of claim 39, wherein the first layer is undoped Al_{0.25}GaN_{0.75}N, the second layer is Si-doped Al_{0.25}Ga_{0.75}N and the third layer is undoped Al_{0.25}Ga_{0.75}N.

43. A high performance high electron mobility transistor structure, comprising:
the AlN nucleation layer, the insulating AlGaN buffer layer, the plurality of insulating AlGaN layers and the undoped GaN layer of the high electron mobility transistor of claim 39;
the AlN nucleation layer, the insulating AlGaN buffer layer, the plurality of insulating AlGaN layers and the undoped GaN layer being transferred onto a second substrate different from the substrate.

44. The high performance high electron mobility transistor structure of claim 43, wherein the second substrate is electrically insulating and thermally conductive.

45. The high performance high electron mobility transistor structure of claim 43, wherein the transistor structure is transferred to the second substrate using an electrically insulating and thermally conductive bonding layer.

46. The high performance high electron mobility transistor structure of claim 45, wherein the bonding layer comprises one of at least a polymer and SiO₂.

47. The high performance high electron mobility transistor structure of claim 44, wherein the electrically insulating and thermally conductive second substrate comprises at least one of diamond, AlN and boron nitride.

48. A Field Effect Transistor structure, comprising:
a source electrode and a drain electrode through the first, second and third AlGaN layers of the high electron mobility transistor structure of claim 39, the source electrode and the drain electrode being in electrical contact with the undoped GaN layer; and
a gate electrode formed over the third AlGaN layer.

49. The Field Effect Transistor structure of claim 48, wherein the source electrode and the drain electrode are made of an alloy containing Ti and Al.

50. The Field Effect Transistor structure of claim 48, wherein the gate electrode comprises Pd.
